(19) United States
(12) Patent Application Publication
(10) Pub. No.: US 2017/0133443 A1
(43) Pub. Date: May 11, 2017

(54) ORGANIC EL DISPLAY PANEL AND METHOD FOR MANUFACTURING ORGANIC EL DISPLAY PANEL

(71) Applicants: JOLED INC., Tokyo (JP); JAPAN DISPLAY INC., Tokyo (JP)

(72) Inventor: Kenichi NENDAI, Tokyo (JP)

(73) Assignees: JOLED INC., Tokyo (JP); JAPAN DISPLAY INC., Tokyo (JP)

(21) Appl. No.: 15/347,116

(22) Filed: Nov. 9, 2016

(30) Foreign Application Priority Data
Nov. 10, 2015 (JP) 2015-220424

(51) Int. Cl. H01L 27/32; H01L 51/56; H01L 51/52

(52) U.S. Cl. CPC H01L 27/3246; H01L 27/3258; H01L 51/5206; H01L 51/56; H01L 2227/323

(57) ABSTRACT

An organic electroluminescent (EL) display panel which includes: a board; a plurality of planarizing films planarizing unevenness caused by a plurality of driver circuits; a plurality of first banks disposed on surfaces of the plurality of planarizing films; a plurality of anode films disposed between adjacent first banks among the plurality of first banks; and a plurality of second banks on upper portions of the plurality of first banks.

### CROSS REFERENCE TO RELATED APPLICATION

The present application is based on and claims priority of Japanese Patent Application No. 2015-220424 filed on Nov. 10, 2015. The entire disclosure of the above-identified application, including the specification, drawings and claims is incorporated herein by reference in its entirety.

### FIELD

The present disclosure relates to an organic electroluminescent (EL) display panel and a method for manufacturing an organic EL display panel.

### BACKGROUND

An organic EL display panel includes a plurality of driver circuits arranged in a matrix on a board and a plurality of organic EL elements connected with the driver circuits. Each organic EL element includes a pair of electrodes, namely, one anode and one cathode, and a functional layer such as an organic luminescent layer interposed between the paired electrodes. Planarizing films planarizing the unevenness caused by the driver circuits are formed between the driver circuits and the organic EL elements.

In the case of forming the organic luminescent layer by a coating method, a region defined by banks projecting from the planarizing films is filled with a liquid substance and then dried, so as to form an organic luminescent layer having a desired thickness between the banks.

The thickness of the organic luminescent layer affects the luminance etc., of light emitted, and thus Patent Literature 1 (PLT 1), for example, disposes a lyophobic film over the upper portion of the inclined side surface of the banks to control the wettability of the portion in contact with the liquid substance and achieve a uniform thickness of the organic luminescent layer.

### CITATION LIST

### Patent Literature

[PTL 1] Japanese Unexamined Patent Application Publication No. 2010-97956

### SUMMARY

### Technical Problem

In recent years, however, the resolution of organic EL display panels has become increasingly higher, and the distance between adjacent banks is decreasing. Such a decrease in the distance between adjacent banks reduces the area of the opening through which light is extracted, thereby decreasing the light extraction efficiency.

Making the banks transparent in order to increase the light extraction efficiency causes light to pass through the banks, resulting in mixing of colors.

The present disclosure has been conceived in view of the above circumstances, and has an object to provide an organic EL display panel and a method for manufacturing an organic EL display panel which reduce mixing of colors between adjacent pixels and increase the light extraction efficiency.

### Solution to Problem

In order to achieve the object described above, an organic EL display panel according to the present disclosure is an organic electroluminescent (EL) display panel including: a plurality of organic EL elements; a plurality of driver circuits which drive the plurality of organic EL elements; a board; a plurality of planarizing films having insulating properties and planarizing unevenness caused by the plurality of driver circuits disposed on the board; a plurality of first banks protruding from surfaces of the plurality of planarizing films; a plurality of anode films disposed on the plurality of planarizing films between adjacent first banks among the plurality of first banks, and connected with the plurality of driver circuits; and a plurality of second banks on upper portions of the plurality of first banks.

Furthermore, in order to achieve the object described above, a method for manufacturing an organic EL display panel according to the present disclosure is a method for manufacturing an organic electroluminescent (EL) display panel including a plurality of organic EL elements and a plurality of driver circuits which drive the plurality of organic EL elements, the method including: forming the plurality of driver circuits on a board; forming a plurality of planarizing films having insulating properties and planarizing unevenness caused by the plurality of driver circuits formed on the board; forming a plurality of first banks protruding from the plurality of planarizing films; forming a plurality of anode films connected with the plurality of driver circuits between adjacent first banks among the plurality of first banks; and forming a plurality of second banks on upper portions of the plurality of first banks.

### Advantageous Effects

According to the present disclosure, mixing of colors of light between pixels can be reduced using the first banks. Furthermore, the light extraction efficiency can be increased because the anode films are formed without having the edge portions covered by the first banks. In addition, when forming the organic luminescent layer by a coating method, the thickness of the organic luminescent layer can be effectively controlled because the shape of a liquid substance applied between banks can be controlled using the second banks.

### BRIEF DESCRIPTION OF DRAWINGS

These and other objects, advantages and features of the present disclosure will become apparent from the following description thereof taken in conjunction with the accompanying drawings that illustrate a specific embodiment of the present disclosure.

[FIG. 1]

FIG. 1 is a cross section diagram illustrating part of an organic EL display panel.

[FIG. 2]

FIG. 2 is a cross section diagram illustrating part of an organic EL display panel which corresponds to one pixel.

[FIG. 3]

FIG. 3 is a diagram illustrating an example of a circuit configuration of a driver circuit which causes an organic EL element to emit light.

[FIG. 4]

FIG. 4 is a diagram illustrating a difference in the area of an effective thickness region depending on the height of a pinning point.

[FIG. 5]

FIG. 5 is a diagram illustrating in (a)-(h) manufacturing processes for an organic EL display panel in order.

[FIG. 6]

FIG. 6 is a cross section diagram illustrating part of an organic EL display panel corresponding to one pixel according to another aspect.

[FIG. 7]

FIG. 7 is a cross section diagram illustrating part of an organic EL display panel corresponding to one pixel according to yet another aspect.

### DESCRIPTION OF EMBODIMENT

The following describes an embodiment of an organic EL display panel and a method for manufacturing an organic EL display panel according to the present disclosure with reference to the Drawings. It should be noted that the embodiment described below is merely an example of the organic EL display panel and the method for manufacturing an organic EL display panel according to the present disclosure. As such, the scope of the present disclosure is demarcated by the recitations in the Claims using the below embodiment as a reference, and is not intended to be limited merely by the following embodiment. Therefore, among the structural elements in the following embodiment, structural elements not recited in any of the independent claims indicating the most generic part of the inventive concept are described as arbitrary structural elements.

The Drawings are schematic illustrations in which emphasis, omission, adjustment in proportion are made as appropriate to illustrate the present disclosure, and may differ from the actual shape, positional relationship, and proportion.

### Organic EL Display Panel

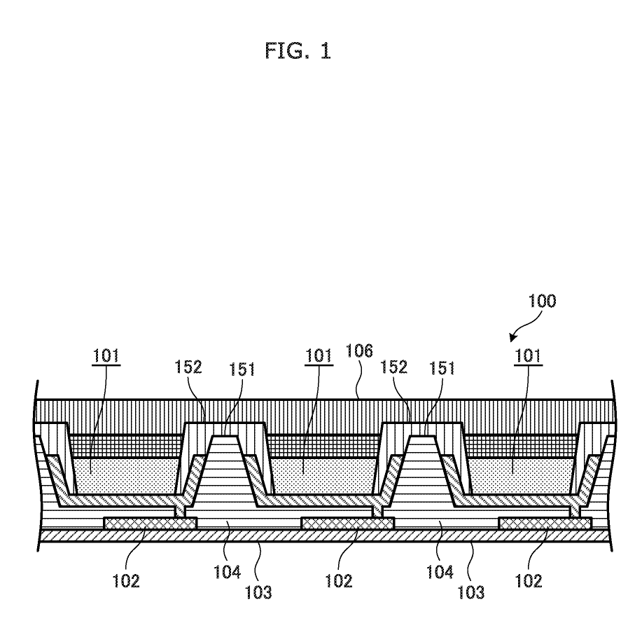

FIG. 1 is a cross section diagram illustrating part of an organic EL display panel.

As illustrated in FIG. 1, an organic EL display panel 100 is a panel for displaying images, for example, and includes a plurality of organic EL elements 101 disposed in a matrix and a plurality of driver circuits 102 which drive the organic EL elements 101. It should be noted that the organic EL display panel 100 according to the present embodiment will be described as a top-emission type organic EL display panel.

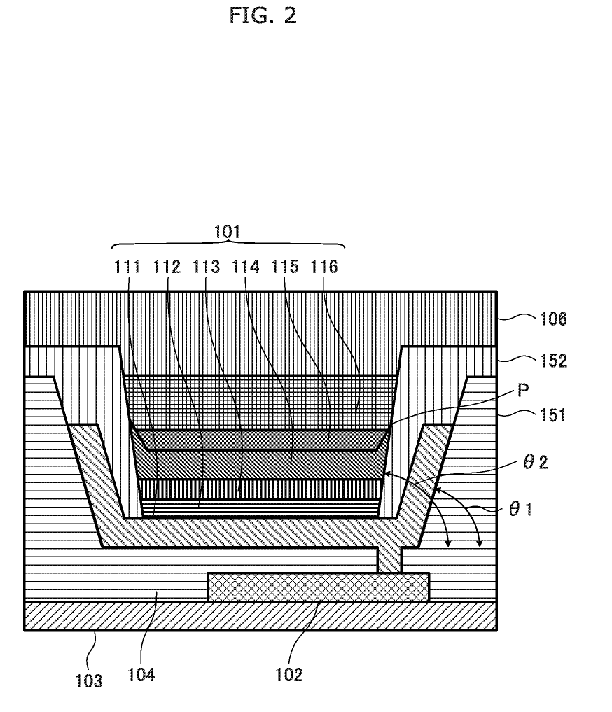

FIG. 2 is a cross section diagram illustrating part of an organic EL display panel corresponding to one pixel.

As illustrated in FIG. 2, the organic EL display panel 100 specifically includes a board 103, a planarizing film 104, first banks 151, second banks 152, an anode film 111, a hole injection layer 112, an interlayer 113, an organic luminescent layer 114, an electron injection layer 115, a cathode film 116, and a sealing film 106. It should be noted that each of the organic EL elements 101 includes the anode film 111, the hole injection layer 112, the interlayer 113, the organic luminescent layer 114, the electron injection layer 115, and the cathode film 116, and that the hole injection layer 112, the interlayer 113, the organic luminescent layer 114 and the electron injection layer 115 are referred to as a functional layer.

The board 103 is a platy member which forms the structural foundation of the organic EL display panel 100. The material of the board 103 is not particularly limited. For example, an insulating material may be used. Examples of the material of the board 103 include glass, polyethylene terephthalate (PET), polyethylene naphthalate (PEN), and polyimide (PI).

Each of the driver circuits 102 is a circuit which drives the organic EL element 101 with which the driver circuit 102 is connected, using a current required, so as to cause the organic EL element 101 to emit light of a type required. Each driver circuit 102 is constituted by a combination of a plurality of thin-film transistors (TFTs).

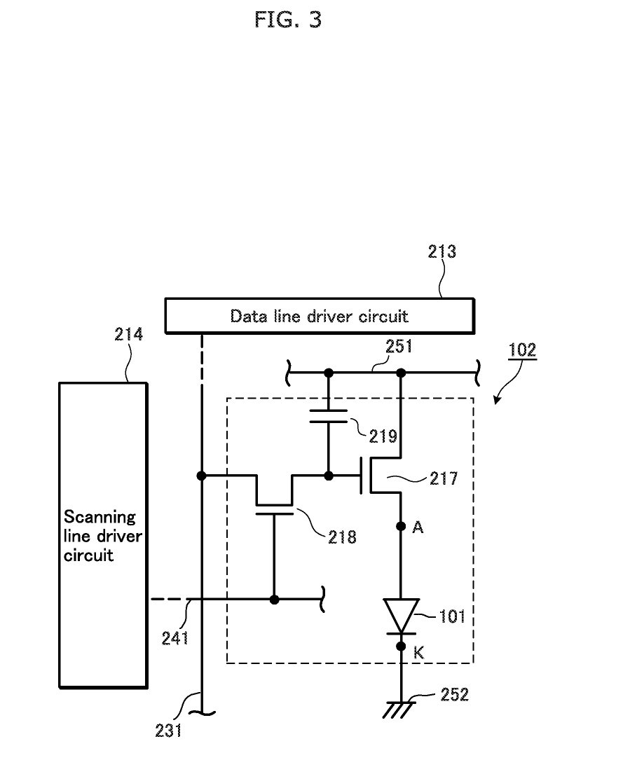

FIG. 3 is a diagram illustrating an example of a circuit configuration of a driver circuit which causes an organic EL element to emit light.

The driver circuit 102 illustrated in FIG. 3 includes a driving transistor 217, a selection transistor 218, and a capacitor 219. A data line 231 is disposed for each column of the organic EL elements 101 disposed in a matrix, and a scanning line 241 is disposed for each row of the organic EL elements 101. Furthermore, a positive power source line 251 and a negative power source line 252 are disposed to be shared by all the organic EL elements 101. The drain electrode of the selection transistor 218 is connected to the data line 231, the gate electrode of the selection transistor 218 is connected to the scanning line 241, and the source electrode of the selection transistor 218 is connected to the capacitor 219 and the gate electrode of the driving transistor 217. The source electrode of the driving transistor 217 is connected to the positive power source line 251, and the drain electrode of the driving transistor 217 is connected to the anode film 111 (anode) of the organic EL element 101.

The planarizing film 104 is an insulating film planarizing the unevenness caused by the plurality of driver circuits 102 disposed on the board 103. As the material of the planarizing film 104, both an organic material and an inorganic material are possible, so long as the material has insulating properties. Specifically, examples of the material of the planarizing film 104 include an inorganic material such as silicon oxide, and a polyimide, acrylic, cyclotene, or novolac organic material.

In the present embodiment, a positive photopolymer material is adopted because the planarizing film 104 integrally includes a first bank 151.

Each of the first banks 151 is a partition wall protruding from the surface of the planarizing film 104, and is a partition between adjacent organic EL elements 101. Each first bank 151 may be a pixel bank or a line bank.

Although it is only necessary that the first banks 151 be formed from an insulating material, the first banks 151 may be formed from a material which shields visible light, in order to reduce mixing of colors between adjacent organic EL elements 101. Furthermore, since the first banks 151 are subjected to treatments such as etching treatment and baking treatment in some cases during the manufacturing process for the organic EL display panel 100, the first banks 151 may be formed from a material which exhibits high resistance to such treatments.

In the present embodiment, the first banks 151 are integrally formed with corresponding planarizing films 104 in the same forming process as for the planarizing films 104, and thus the first banks 151 are formed from the same positive photopolymer material as for the planarizing films 104.

Although the shape of the first banks 151 is not particularly limited, an example is such a forward tapered shape that the distance between adjacent first banks 151 increases as the distance from the planarizing films 104 increases as illustrated in FIG. 2. It should be noted that FIG. 2 is a schematic diagram and both of the inclined side surfaces of the first banks 151 are curved surfaces which bulge out.

Although the inclination angle θ1 of the inclined side surfaces of the first banks 151 is not particularly limited, it is preferably in a range from 20° to 90°, more preferably in a range from 30° to 50°.

Furthermore, although the height of the first banks 151 is not particularly limited, it is about 0.3 μm to 3 μm.

The first banks 151 may be lyophilic. This is because the adhesion etc., when forming the anode film 111 on the surfaces of the planarizing films 104 and the first banks 151 can be increased.

The second banks 152 are disposed on the upper portions of the first banks 151 and are more lyophobic than the first banks 151.

Although it is only necessary that the second banks 152 be formed from an insulating material, the second banks 152 may have higher resistance to organic solvents than the first banks 151 because the second banks 152 come in contact with a liquid substance forming the organic luminescent layer 114. Furthermore, the second banks 152 may be transparent to light emitted by the organic EL elements 101, in order to increase the efficiency of light extraction from the organic EL elements 101. Here, in the case where the organic EL elements 101 emit visible red, green, and blue light, second banks 152 may be transparent to the light of all of these colors. Moreover, like the first banks 151, the second banks 152 may be formed from a material which exhibits high resistance to treatments such as etching treatment and baking treatment.

The material of the second banks 152 may be an organic material such as a resin or an inorganic material such as glass. Examples of the organic material include an acrylic resin, a polyimide resin, a novolac-type phenolic resin. Examples of the inorganic material include silicon oxide and silicon nitride.

In the present embodiment, the second banks 152 are formed using a negative photopolymer material different from the material of the first banks 151. This facilitates the formation of the second banks 152 in any shape at any position over the first banks 151.

Although the shape of the second banks 152 is not particularly limited, the inclination angle θ2 of the inclined side surfaces of the second banks 152 is greater than the inclination angle θ1 of the inclined side surfaces of the first banks 151 as illustrated in FIG. 2. Moreover, the inclination angle θ2 of the inclined side surfaces of the second banks 152 with respect to the board 103 may be 90°, or greater than 90° such that the upper portions of the second banks 152 overhang.

In the present embodiment, each of the second banks 152 and a corresponding first bank 151 sandwich the edges of the anode film 111 extending along the foot portion of the first bank 151. Furthermore, the second banks 152 cover the upper portions of the first banks 151 (see FIG. 1).

Although the total height of the first banks 151 and the second banks 152 is not particularly limited, it is preferably in a range from about 0.3 μm to 3 μm, for example.

Furthermore, at least the surface of the second banks 152 may be lyophobic. With this, even when the region between adjacent second banks 152 is filled with a liquid substance such that the liquid substance becomes higher than the second banks 152, surface tension of the liquid substance makes it possible to reduce the possibility of leakage of the liquid substance outside the second banks 152.

In the present embodiment, the second banks 152 are formed from a photopolymer material to which a fluorine material is added to ensure lyophobicity. In this case, the fluorine material floats up when forming the second banks 152, rendering the upper portions of the second banks 152 relatively high in lyophobicity. In the present embodiment, however, the second banks 152 are thinner than the first banks 151 and the fluorine material does not float up so much, thereby rendering even the lower portions of the second banks 152 lyophobic.

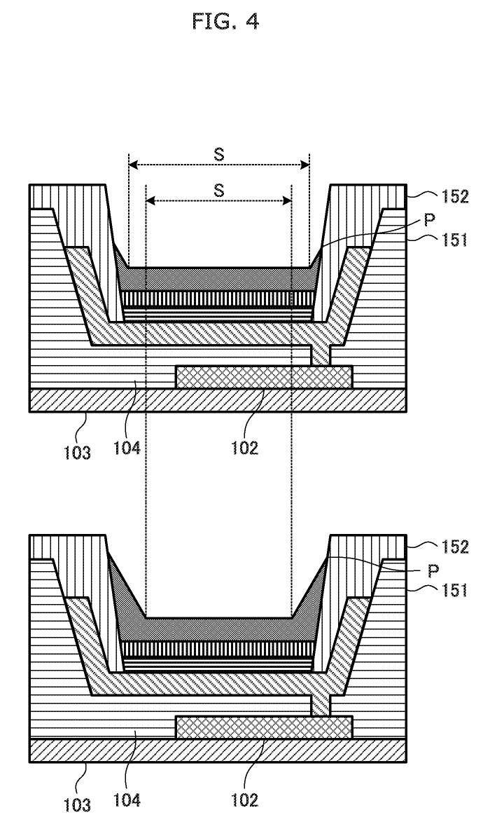

Here, a position at which a droplet of the liquid substance (for example, ink including a raw material of the organic luminescent layer) applied to the region between adjacent second banks 152 shows self-pinning when the critical concentration is reached during drying is referred to as a pinning point P. As illustrated in FIG. 4, in general, the lower the pinning point P is, the less the peripheral portion of the liquid substance applied to the region between the adjacent second banks 152 rises along the second banks 152 due to wetting, thereby enabling an increase in the area of an effective thickness region S having a uniform thickness. The pinning point P is generated at the boundary between the lyophobicity and the lyophilicity. In the present embodiment, the position of the pinning point P can be lowered, thereby enabling an increase in the area of the effective thickness region S of the organic luminescent layer 114, for example. This makes it possible to provide the organic EL display panel 100 which is high in luminance.

It should be noted that the terms “lyophobic” and “lyophilic” are used in a relative sense, describing that the portion above the pinning point P is lyophobic and the portion below the pinning point P is lyophilic; however, there is no clear boundary because “lyophobicity” and “lyophilicity” vary depending on the variation degree.

The anode film 111 is an electrode disposed on the planarizing film 104 between adjacent first banks 151 and connected with the driver circuit 102.

In the present embodiment, the organic EL display panel 100 is a top-emission type organic EL display panel, and the anode film 111 functions as a reflective anode having light reflecting properties. The anode film 111 having light reflecting properties is constituted by a monolayer or a plurality of layers. Examples of the material of the anode film 111 include silver (Ag), a silver-palladium-copper (APC) alloy, a silver-rubidium-gold (ARA) alloy, a molybdenum-chrome (MoCr) alloy, a nickel-chrome (NiCr) alloy, and an aluminum (AL) alloy.

In the present embodiment, both edge portions of the anode film 111 extend along the inclined side surfaces of adjacent first banks 151. This structure is obtained by forming the anode film 111 after forming the first banks 151. Adopting this structure allows utilization of the edge portions of the anode film 111 as reflective surfaces, making it possible to reflect the light emitted from the organic EL elements 101 toward the first banks 151 and the second banks 152 and thereby increase the light extraction efficiency.

The hole injection layer 112 has a function to increase the efficiency of hole injection from the anode film 111. Examples of the material of the hole injection layer 112 include organic materials such as polyethylenedioxythiophene doped with polystyrene sulfonate (PEDOT-PSS), poly (3,4-ethylenedioxythiophene) and derivatives thereof.

The interlayer 113 is a layer having a function to efficiently transport holes to the organic luminescent layer 114. Examples of the material of the interlayer 113 include triphenylamine and polyaniline.

The organic luminescent layer 114 is a layer including an organic luminescent material which emits light when electric power corresponding to luminescent colors such as red (R), green (G), and blue (B) is supplied. Examples of the organic luminescent material included in the organic luminescent layer 114 include polyphenylene vinylene and derivatives thereof, polyacetylene and derivatives thereof, polyphenylene and derivatives thereof, poly(p-phenylene) ethylene and derivatives thereof, poly(3-hexylthiophene) and derivatives thereof, and polyfluorene and derivatives thereof.

The electron injection layer 115 is a layer which transports electrons injected from the cathode film 116 to the organic luminescent layer 114. Examples of the material of the electron injection layer 115 include barium, phthalocyanine, lithium fluoride, and a combination of these.

The cathode film 116 is a film which supplies electrons to the organic luminescent layer 114 for light emission. In the present embodiment, the organic EL display panel 100 is a top-emission type organic EL display panel, and thus the cathode film 116 is formed from a transparent material, such an indium tin oxide (ITO) film, through which visible light easily passes.

The sealing film 106 is a film disposed on the cathode film 116 and reduces exposure of the organic EL elements 101 etc., to moisture and air. The sealing film 106 may be connected with adjacent organic EL elements 101 across the region defined by the first banks 151 and the second banks 152. In the present embodiment, the organic EL display panel 100 is a top-emission type organic EL display panel, and thus the sealing film 106 is formed from a transparent material which can transmit visible light emitted from each organic EL element 101.

### Method for Manufacturing Organic EL Display Panel

The following describes a method for manufacturing the organic EL display panel 100 including a plurality of organic EL elements 101 and a plurality of driver circuits 102 which drive the organic EL elements 101.

Generally stated, the method for manufacturing the organic EL display panel 100 includes the following:

1) forming a plurality of driver circuits 102 on a board 103,

2) forming a plurality of planarizing films 104 planarizing unevenness caused by the plurality of driver circuits 102,

3) forming a plurality of first banks 151 protruding from the plurality of planarizing films 104,

4) forming a plurality of anode films 111 connected with the plurality of driver circuits 102 between adjacent first banks 151 among the plurality of first banks 151,

5) forming a plurality of second banks 152 which are more lyophobic than the first banks 151, on upper portions of the plurality of first banks 151, and

6) forming a functional layer including an organic luminescent layer, in a region defined by the banks.

### Forming Driver Circuits

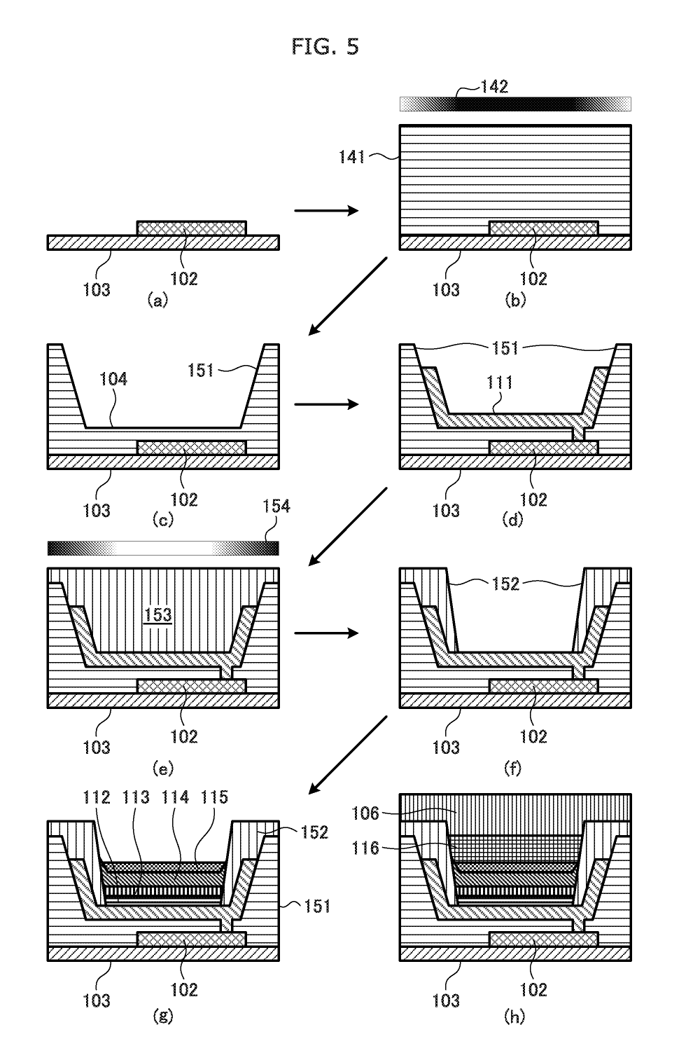

As illustrated in (a) of FIG. 5, each driver circuit 102 is formed on the board 103 using a common method. For example, a gate electrode is formed on the board 103 such as a glass board, by physical vapor deposition or chemical vapor deposition, and then a gate insulating layer is formed on the board 103 to cover the gate electrode. In addition, a source electrode and a drain electrode (hereinafter collectively referred also to as “SD electrodes”) are formed on the gate insulating layer at positions separate from each other, and then a semiconductor layer is formed to cover the SD electrodes, thereby forming the driver circuit 102.

### Forming Planarizing Films and Forming First Banks

Next, as illustrated in (b) of FIG. 5, a positive photopolymer material 141 is applied to the board 103 on which the driver circuit 102 is disposed, until the surface of the liquid becomes flat. Subsequently, a planarizing film 104 and first banks 151 are formed as illustrated in (c) of FIG. 5, by irradiating a given position of the photopolymer material 141 with light using a half-tone mask 142, for example.

It should be noted that the planarizing film 104 and the first banks 151 may be formed in different processes. Furthermore, either of the planarizing film 104 and the first banks 151 or both of the planarizing film 104 and the first banks 151 may be formed from an inorganic material by chemical vapor deposition, for example.

### Forming Anode Films

Next, as illustrated in (d) of FIG. 5, an anode film 111 is formed between adjacent first banks 151 such that the end portions of the anode film 111 extend along the inclined side surfaces of the first banks 151. Examples of the method for forming the anode films 111 include vapor deposition and sputtering. The anode films 111 may also be formed by photolithography.

### Forming Second Banks

As illustrated in (e) of FIG. 5, a negative photopolymer material 153 is applied to the board 103 on which the anode film 111 is disposed, until the liquid level exceeds the first banks 151. Subsequently, as illustrated in (f) of FIG. 5, the second banks 152 are formed by irradiating a given position of the photopolymer material 153 with light using a mask 154, for example.

It should be noted that the use of the negative photopolymer material 153 enables easy adjustment of the inclination of the inclined side surfaces of the second banks 152. For example, the inclined side surfaces of the second banks 152 may be made vertical or in an overhang manner, or in such a manner that the end portions of the anode film 111 extending along the inclined side surfaces of the first banks 151 are partially exposed.

It is considered possible to adjust the height of the pinning point P by changing the inclination angle of the inclined side surfaces of the second banks 152. For example, when the inclined side surfaces of the second banks 152 are made vertical or in an overhang manner, the pinning point P can be lowered.

In addition, the vertex portions of the first banks 151 can be exposed by applying the photopolymer material 153 up to a level below the first banks 151. Furthermore, the second banks 152 may be formed from an inorganic material by chemical vapor deposition, for example.

### Forming Functional Layer

Next, as illustrated in (g) of FIG. 5, a functional layer including the hole injection layer 112, the interlayer 113, the organic luminescent layer 114, and the electron injection layer 115 is formed in a region defined by the second banks 152, by a sequential coating method. Examples of the coating method include inkjet-printing, dispensing, nozzle coating, spin coating, intaglio printing, and relief printing. Each layer is applied and then dried to form the layer. It should be noted that although the Drawings do not precisely show the thickness of each layer, the organic luminescent layer 114 has the largest thickness, and the size of the effective thickness region S is determined almost at the time of forming the organic luminescent layer 114.

### Forming Cathode Films

Next, a cathode film 116 (material: ITO, thickness: 100 nm) such as ITO is formed on the electron injection layer 115 by sputtering, for example. Lastly, a sealing film 106 is formed over the entire board 103.

The organic EL display panel 100 is manufactured by the method described above.

With the organic EL display panel 100 and the method for manufacturing an organic EL display panel described above, the anode film 111 which functions as a reflective film is formed after the first banks, thereby making it possible to easily control the shape of the anode film 111 using the shape of the first banks 151 including the planarizing films 104. Accordingly, it is possible to easily achieve the structure in which the light emitted from the organic luminescent layer 114 is effectively reflected, thereby enabling an increase in the light extraction efficiency.

Furthermore, since insulation can be ensured by the second banks 152 even when the anode film 111 extends close to the cathode film 116, it is possible to reduce occurrence of malfunction such as a short circuit.

In addition, forming the first banks 151 and the second banks 152 from different materials makes it possible to reduce mixing of luminescent colors between adjacent organic EL elements 101, and making the second banks 152 transparent makes it possible to increase the light extraction efficiency. Moreover, this allows the total height of the first banks 151 and the second banks 152 to be higher, making it possible to reduce mixing of liquid substances beyond the banks when forming the organic luminescent layer 114.

Furthermore, with the inclination angle of the inclined side surfaces of the second banks 152 and the fluorine material included in the second banks 152, it is possible to lower the pinning point P which is brought about when forming the organic luminescent layer 114, thereby enabling an increase of the effective thickness region S of the organic luminescent layer 114.

Although only an exemplary embodiment of the present disclosure has been described in detail above, those skilled in the art will readily appreciate that many modifications are possible in the exemplary embodiment without materially departing from the novel teachings and advantages of the present disclosure. Accordingly, all such modifications are intended to be included within the scope of the present disclosure.

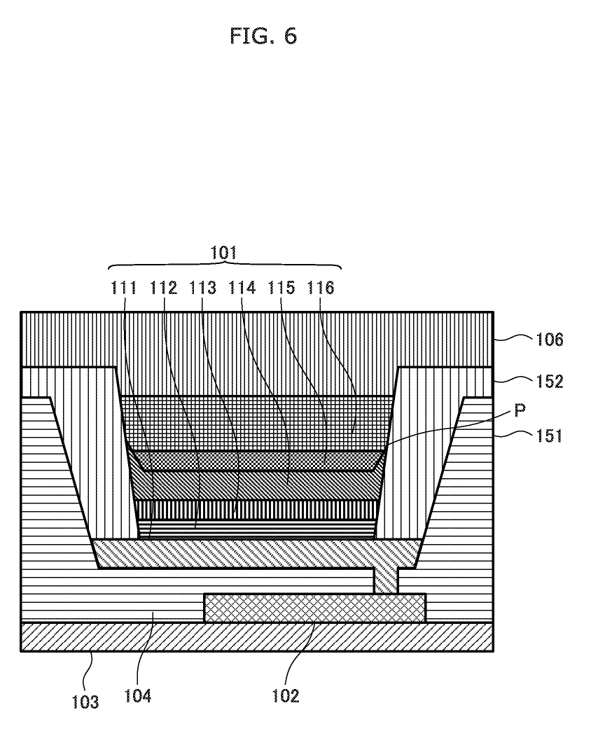

For example, the edge portions of the anode film 111 need not extend along the foot portions of the first banks 151 as illustrated in FIG. 6.

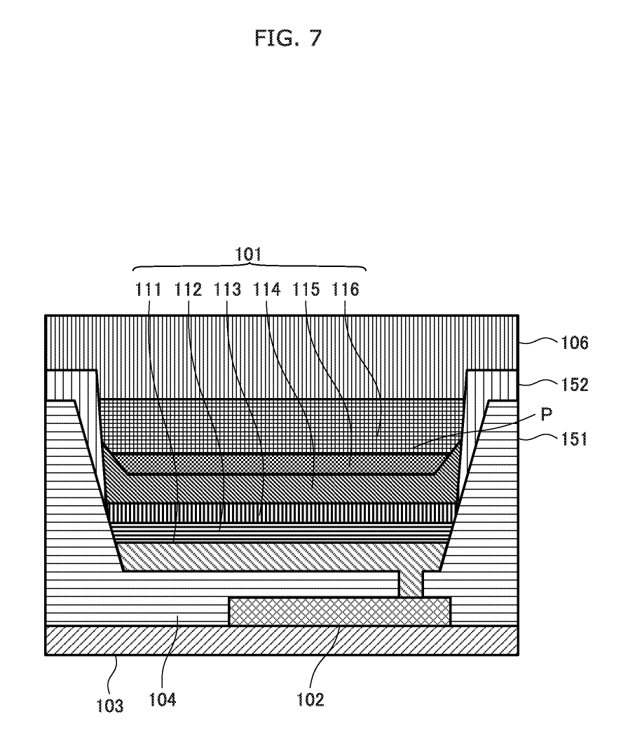

Furthermore, as illustrated in FIG. 7, the second banks 152 need not be in contact with the anode film 111. Moreover, the lower ends of the second banks 152 may be located at an intermediate position of the inclined side surfaces of the first banks 151. With this, the boundary between the first banks 151 which are lyophilic and the second banks 152 which are lyophobic can be clearly made, enabling effective control of the pinning point P.

1. An organic electroluminescent (EL) display panel comprising:
a plurality of organic EL elements;
a plurality of driver circuits which drive the plurality of organic EL elements;
a board;
a plurality of planarizing films having insulating properties and planarizing unevenness caused by the plurality of driver circuits disposed on the board;
a plurality of first banks protruding from surfaces of the plurality of planarizing films;
a plurality of anode films disposed on the plurality of planarizing films between adjacent first banks among the plurality of first banks, and connected with the plurality of driver circuits; and
a plurality of second banks on upper portions of the plurality of first banks.

2. The organic EL display panel according to claim 1,
wherein an inclination angle of inclined side surfaces of the plurality of second banks with respect to the surfaces of the plurality of planarizing films is greater than an inclination angle of inclined side surfaces of the plurality of first banks with respect to the surfaces of the plurality of planarizing films.

3. The organic EL display panel according to claim 1,
wherein edge portions of the plurality of anode films extend along inclined side surfaces of the plurality of first banks.

4. The organic EL display panel according to claim 1,
wherein the plurality of second banks are transparent to light emitted by the plurality of organic EL elements and cover edges of the plurality of anode films.

5. The organic EL display panel according to claim 1,
wherein each of the plurality of first banks is integrally formed with a corresponding one of the plurality of planarizing films.

6. A method for manufacturing an organic electroluminescent (EL) display panel including a plurality of organic EL elements and a plurality of driver circuits which drive the plurality of organic EL elements, the method comprising:
forming the plurality of driver circuits on a board;
forming a plurality of planarizing films having insulating properties and planarizing unevenness caused by the plurality of driver circuits formed on the board;
forming a plurality of first banks protruding from the plurality of planarizing films;
forming a plurality of anode films connected with the plurality of driver circuits between adjacent first banks among the plurality of first banks; and
forming a plurality of second banks on upper portions of the plurality of first banks.
